(19) United States
(12) Patent Application Publication
(10) Pub. No.: US 2023/0085752 A1
(43) Pub. Date: Mar. 23, 2023

(54) DISPLAY PANEL AND METHOD FOR MANUFACTURING DISPLAY PANEL, AND DISPLAY DEVICE

(71) Applicant: Hubei Yangtze Industrial Innovation Center Of Advanced Display Co., Ltd., Wuhan (CN)

(72) Inventor: Qijun YAO, Wuhan (CN)

(73) Assignee: Hubei Yangtze Industrial Innovation Center Of Advanced Display Co., Ltd., Wuhan (CN)

(21) Appl. No.: 18/054,147

(22) Filed: Nov. 10, 2022

(30) Foreign Application Priority Data
Jun. 1, 2022 (CN) 202210616713.5

(51) Int. Cl. H01L 33/50; H01L 27/15; H01L 33/00

(52) U.S. Cl. CPC H01L 33/505; H01L 27/156; H01L 33/005; H01L 2933/0041

(57) ABSTRACT

A display panel and a method for manufacturing the display panel, and a display device are provided. The display panel includes: a first substrate and a second substrate which are arranged opposite to each other; a metal bank located between the first substrate and the second substrate, where the metal bank includes multiple openings, and at least some of the openings are each provided with a light conversion layer; and light emitting elements located between the light conversion layers and the second substrate. When the light conversion layer converts the light emitted from the light emitting element into the light with the corresponding color, the light from the adjacent openings is blocked by the metal bank, and to avoid light mixing in the adjacent openings, to improve the display effect of the display device.

### CROSS REFERENCE OF RELATED APPLICATION

The present disclosure claims priority to Chinese Patent Application No. 202210616713.5, titled “DISPLAY PANEL AND METHOD FOR MANUFACTURING DISPLAY PANEL, AND DISPLAY DEVICE”, filed on Jun. 01, 2022 with the China National Intellectual Property Administration, which is incorporated herein by reference in its entirety.

### FIELD

The present disclosure relates to the field of display, and in particular, to a display panel and a method for manufacturing the display panel, and a display device.

### BACKGROUND

Light-emitting diode (LED) has advantages such as low power consumption and high brightness, while photoluminescence quantum dot (QD) material has advantages such as wide color gamut and pure light color. Therefore, the display technology utilizing LED plus QD structure has gradually become one of the research hotspots. In such display technology, the red and green photoluminescence QD materials are stimulated by blue light from the LED, to realize full color display. However, light mixing between pixels often occurs in the existing display device, resulting in poor display effect of the display device.

### SUMMARY

In view of this, a display panel and a method for manufacturing the display panel, and a display device are provided according to the present disclosure, to effectively solve the existing problem, to improve the display effect of the display device.

In order to solve the above problem, the following embodiments are provided according to the present disclosure.

A display panel includes:
a first substrate and a second substrate which are arranged opposite to each other;
a metal bank located between the first substrate and the second substrate, where the metal bank includes multiple openings, at least some of the openings are each provided with a light conversion layer;
light emitting elements located between the light conversion layers and the second substrate, where the light conversion layers are arranged corresponding to at least some of the light emitting elements.

In addition, a display device is provided according to the present disclosure. The display device includes the above display panel.

In addition, a method for manufacturing the above display panel is provided according to the present disclosure. The method includes:
providing a first substrate and a second substrate;
forming a metal bank located between the first substrate and the second substrate, light conversion layers and light emitting elements, where the metal bank includes multiple openings, at least some of the openings are provided with the light conversion layers; and the light emitting elements are located between the light conversion layers and the second substrate, where the light conversion layers are arranged corresponding to at least some of the light emitting elements.

Compared with the conventional technology, the embodiments provided according to the present disclosure have at least the following advantages.

A display panel and a method for manufacturing the display panel, and a display device are provided according to the present disclosure. The display panel includes: a first substrate and a second substrate which are arranged opposite to each other; a metal bank located between the first substrate and the second substrate, where the metal bank includes multiple openings, and at least some of the openings are each provided with a light conversion layer; and light emitting elements located between the light conversion layers and the second substrate, where the light conversion layers are arranged corresponding to at least some of the light emitting elements. It can be seen that when the light conversion layer converts the light emitted from the light emitting element into the light with the corresponding color, the light from the adjacent openings is blocked by the metal bank, and to avoid light mixing in the adjacent openings, to improve the display effect of the display device.

### BRIEF DESCRIPTION OF THE DRAWINGS

In order to clearly describe in the embodiments of the present disclosure, drawings to be used in the description of the embodiments of the present disclosure or the conventional technology are briefly described hereinafter. It is apparent that the drawings described below are merely used for describing the embodiments of the present disclosure.

FIG. 1 is a schematic structural diagram of a display panel according to an embodiment of the present disclosure;

FIG. 2 is a sectional view of FIG. 1 along a line of AA';

FIG. 3 is a schematic structural diagram of a display panel according to another embodiment of the present disclosure;

FIG. 4 is a schematic structural diagram of a display panel according to yet another embodiment of the present disclosure;

FIG. 5 is a schematic structural diagram of a display panel according to yet another embodiment of the present disclosure;

FIG. 6 is a schematic structural diagram of a display panel according to yet another embodiment of the present disclosure;

FIG. 7 is a schematic structural diagram of a display panel according to yet another embodiment of the present disclosure;

FIG. 8 is a schematic structural diagram of a display panel according to yet another embodiment of the present disclosure;

FIG. 9 is a schematic structural diagram of a display panel according to yet another embodiment of the present disclosure;

FIG. 10 is a schematic structural diagram of a display panel according to yet another embodiment of the present disclosure;

FIG. 11 is a schematic structural diagram of a display panel according to yet another embodiment of the present disclosure;

FIG. 12 is a schematic structural diagram of a display panel according to yet another embodiment of the present disclosure;

FIG. 13 is a schematic structural diagram of a display panel according to yet another embodiment of the present disclosure;

FIG. 14 is a schematic structural diagram of a display panel according to yet another embodiment of the present disclosure;

FIG. 15 is a schematic structural diagram of a display panel according to yet another embodiment of the present disclosure;

FIG. 16 is a schematic structural diagram of a display panel according to yet another embodiment of the present disclosure;

FIG. 17 is a schematic structural diagram of a display panel according to yet another embodiment of the present disclosure;

FIG. 18 is a schematic structural diagram of a display device according to an embodiment of the present disclosure;

FIG. 19 is a flowchart of a method for manufacturing a display panel according to an embodiment of the present disclosure;

FIG. 20 is a flowchart of a method for preparing a light conversion layer according to an embodiment of the present disclosure;

FIG. 21 is a flowchart of a method for preparing a light conversion layer according to another embodiment of the present disclosure;

FIG. 22a to FIG. 22g are schematic diagrams illustrating structures corresponding to the steps in FIG. 21;

FIG. 23 is a flowchart of a method for preparing metal bank according to an embodiment of the present disclosure; and

FIG. 24a to FIG. 24d are schematic diagrams illustrating structures corresponding to the steps in FIG. 23.

### DETAILED DESCRIPTION OF EMBODIMENTS

The embodiments of the present disclosure will be clearly and completely described hereinafter in conjunction with the drawings in the embodiments of the present disclosure. Apparently, the embodiments described in the following are only some embodiments of the present disclosure, rather than all embodiments.

As mentioned in the background, the display technology utilizing LED plus QD structure has gradually become one of the research hotspots. In such display technology, the red and green photoluminescence QD materials are stimulated by blue light from the LED, to realize full color display. However, light mixing between pixels often occurs in the existing display device, resulting in poor display effect of the display device.

In view of this, a display panel and a method for manufacturing the display panel, and a display device are provided according to the present disclosure, to effectively solve the existing problem, to improve the display effect of the display device.

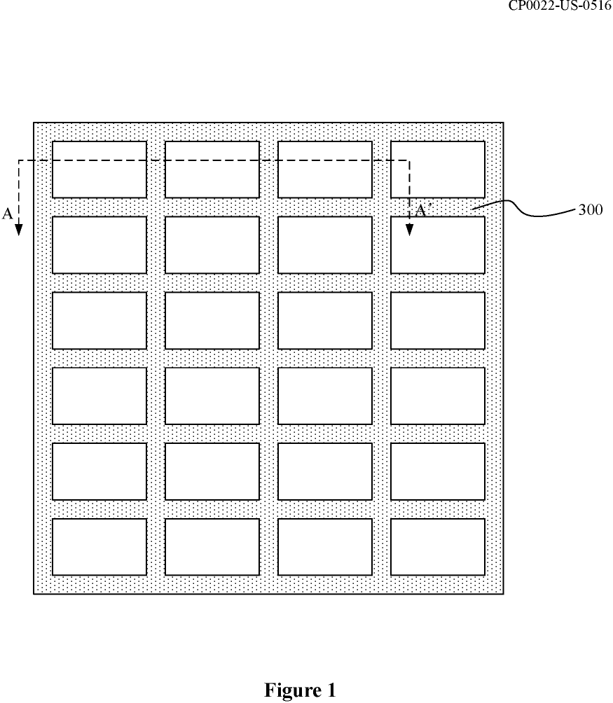

For such purpose, the following embodiments are provided according to the present disclosure, which are described in detail with reference to FIG. 1 to FIG. 24d.

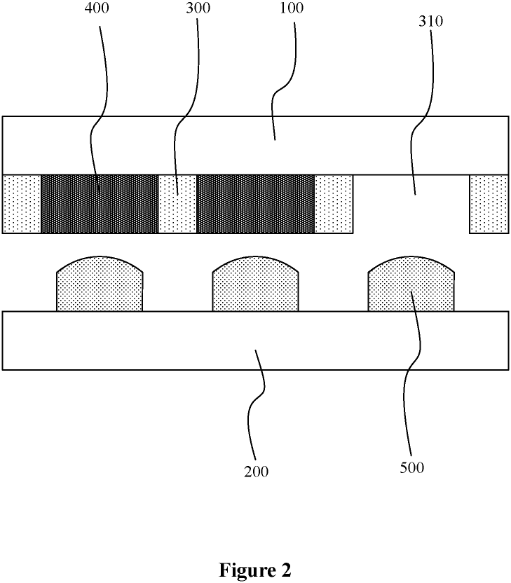

Referring to FIG. 1 and FIG. 2, FIG. 1 is a schematic structural diagram of a display panel according to an embodiment of the present disclosure and FIG. 2 is a sectional view of FIG. 1 along a line of AA'. A display panel according to the present disclosure includes: a first substrate 100 and a second substrate 200 which are arranged opposite to each other.

The display panel further includes a metal bank 300 located between the first substrate 100 and the second substrate 200. The metal bank 300 includes multiple openings 310, and at least some of the openings 310 are each provided with a light conversion layer 400.

The display panel further includes light emitting elements 500 located between the light conversion layers 400 and the second substrate 200. The light conversion layers 400 are arranged corresponding to at least some of the light emitting elements 500.

It can be understood that, in the embodiments according to the present disclosure, when the light conversion layer converts the light emitted from the light emitting element into the light with a corresponding color, the light from an adjacent opening is blocked by the metal bank, and to avoid the light mixing in adjacent openings, to improve the display effect of the display device.

In an embodiment of the present disclosure, a material of the metal bank 300 according to an embodiment of the present disclosure includes at least one of Ni and Al. The metal bank 300 according to the present disclosure may be prepared on the first substrate 100, and the light emitting elements 500 according to the present disclosure may be electrically connected to the second substrate 200. The second substrate 200 is an array substrate, and the array substrate includes multiple power supply terminals. The light emitting elements 500 are electrically connected to the power supply terminals to be powered by a circuit on the second substrate 200.

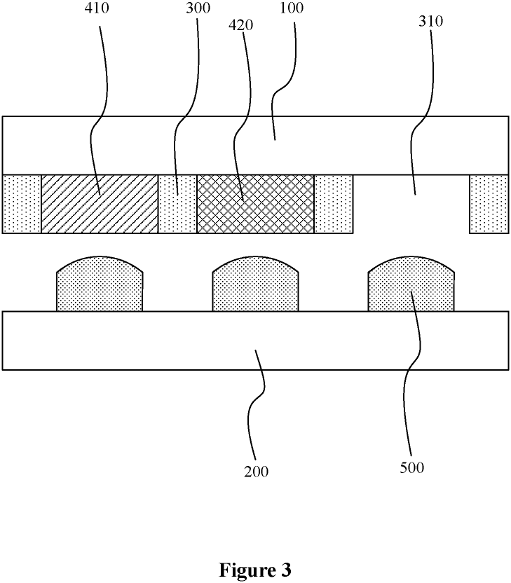

In an embodiment of the present disclosure, the light emitting element 500 according to the present disclosure may be a light-emitting diode. FIG. 3 is a schematic structural diagram of a display panel according to another embodiment of the present disclosure. In the display panel according to the present disclosure, some of the openings 310 are provided with a light conversion layer 400, while some of the openings 310 are not. The light emitting elements 500 according to the present disclosure may emit light of same color; for example, all of the light emitting elements 500 emit blue light. The light conversion layers 400 may include a first color light conversion layer 410 and a second color light conversion layer 420. For example, the first color light conversion layer 410 is configured to convert the light emitted by a light emitting element 500 into green light, and the second color light conversion layer 420 is configured to convert the light emitted by a light emitting element 500 into red light. The light at the opening 310 which is not provided with light conversion layer 400 is directly emitted with its original color emitted from the light emitting element 500. Therefore, display of a picture is performed by the light converted by the light conversion layers 400 and the light directly emitted without the light conversion layer 400.

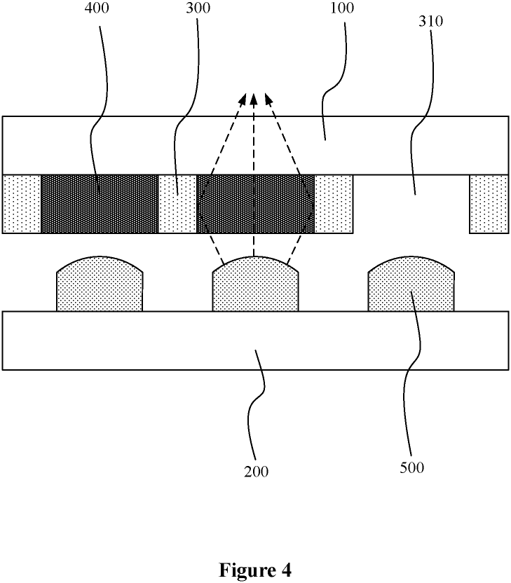

FIG. 4 is a schematic structural diagram of a display panel according to yet another embodiment of the present disclosure. In FIG. 4, the dotted arrows indicate light paths. In the embodiment, the side walls of the metal bank 300 at the openings 310 are formed as reflecting surfaces. The metal bank 300 not only blocks the light crosstalk in the adjacent openings 310, but also reflects light in the openings 310, thus can ensure high light emitting efficiency, to ensure an improved display effect of the display panel. According to an embodiment of the present disclosure, the reflecting surface on the side wall of the metal bank 300 at the opening 310 may be formed by mirror treatment of the side wall.

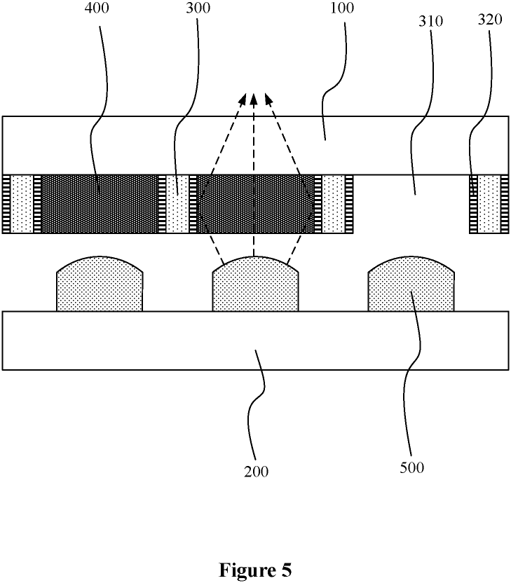

FIG. 5 is a schematic structural diagram of a display panel according to yet another embodiment of the present disclosure. According to an embodiment of the present disclosure, the reflecting surface on the side wall of the metal bank 300 at the opening 310 may be formed by providing a reflective coating on the side wall of the metal bank 300 at the opening 310.

FIG. 6 is a schematic structural diagram of a display panel according to yet another embodiment of the present disclosure. According to an embodiment of the present disclosure, a surface of the metal bank 300 facing away from the first substrate 100 is a non-reflecting surface 340 (indicated in FIG. 6 by symbol X that is at an end position of the light emitted to the side of the metal bank 300 facing away from the first substrate 100), and the metal bank 300 is prevented from reflecting the light emitted from the light emitting elements 500 to the side where the second substrate 200 is located, to reduce crosstalk between adjacent light emitting elements 500. In an embodiment, the non-reflecting surface at the side of the metal bank 300 facing away from the first substrate 100 may be an oxidized surface. In another embodiment, the non-reflecting surface of the metal bank 300 facing away from the first substrate 100 may be a non-reflective coating, which is not limited in the present disclosure.

It can be understood that, in the display panel according to an embodiment of the present disclosure, more light is reflected by the reflecting surfaces on the side wall of the metal bank 300 at the opening 310 to the side where the first substrate 100 is located, and less light is reflected by the non-reflecting surface of the metal bank 300 facing away from the first substrate 100, to the side where the second substrate 200 is located, to reduce light crosstalk between adjacent light emitting elements 500 and ensuring a better display effect of the display panel.

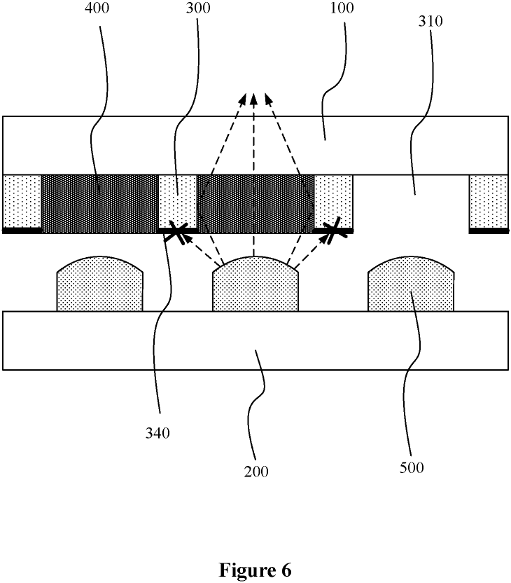

FIG. 7 is a schematic structural diagram of a display panel according to yet another embodiment of the present disclosure. According to the present disclosure, a side of the light emitting element 500 facing away from the second substrate 200 is in contact with a side of the light conversion layer 400 facing away from the first substrate 100. The contact between the light emitting element 500 and the light conversion layer 400 may function to support the first substrate 100 and the second substrate 200. On the basis of ensuring sufficient support for the first substrate 100 and the second substrate 200, reducing the preparation of the support structure between the first substrate 100 and the second substrate 200 can not only improve the effective layout space between the first substrate 100 and the second substrate 200, but also avoid the waste of resources and simplify the manufacturing process.

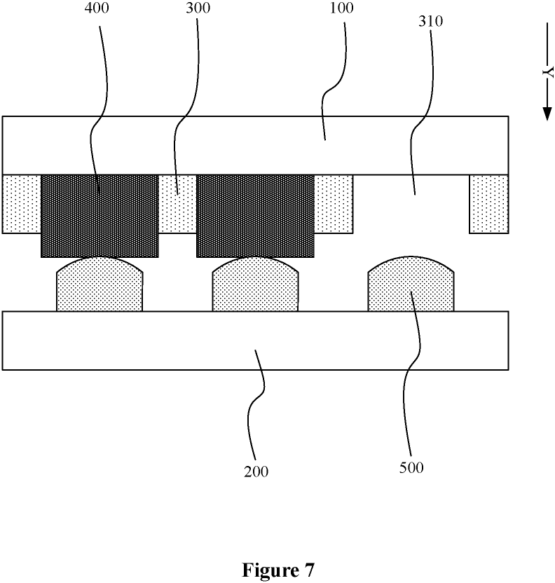

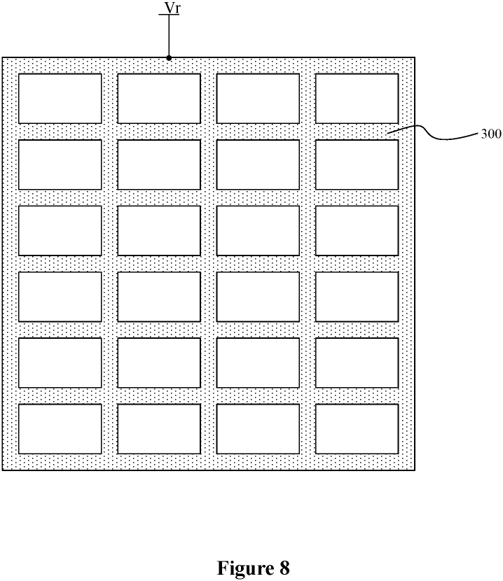

FIG. 8 is a schematic structural diagram of a display panel according to yet another embodiment of the present disclosure. According to the present disclosure, the metal bank 300 is electrically connected to a reference signal terminal Vr, and the electrostatic discharge capability of the display panel is improved by the path between the metal bank 300 and the reference signal terminal Vr. In an embodiment, the reference signal terminal Vr a may be a grounded terminal.

The shape of the metal bank 300 is not limited in the embodiment of the present disclosure. A sectional area of the opening 310 on a surface parallel to the second substrate 200 is gradually increased, decreased, or remains the same in a direction from the first substrate 100 to the second substrate 200. In one embodiment, FIG. 9 is a schematic structural diagram of a display panel according to yet another embodiment of the present disclosure. The sectional area of the opening 310 on the surface parallel to the second substrate 200 is gradually increased in the direction from the first substrate 100 to the second substrate 200. That is, in the direction Y from the first substrate 100 to the second substrate 200, the section of a portion of the metal bank 300 between two adjacent openings (that is, a transection in the direction of AA' shown in FIG. 1) is in a trapezoid shape. That is, a surface area of the metal bank 300, at a side where the first substrate 100 is located, is greater than a surface area at a side where the metal bank 300 faces the second substrate 200. The metal bank 300 with trapezoid sections is easy to manufacture.

As shown in FIG. 7, the sectional area of the opening 310 on the surface parallel to the second substrate 200 remains the same in the direction from the first substrate 100 to the second substrate 200. That is, in the direction Y from the first substrate 100 to the second substrate 200, the section of a portion of the metal bank 300 between two adjacent openings (that is, a transection in the direction of AA' shown in FIG. 1) is in a rectangular shape. The metal bank 300 with rectangular sections is also easy to manufacture.

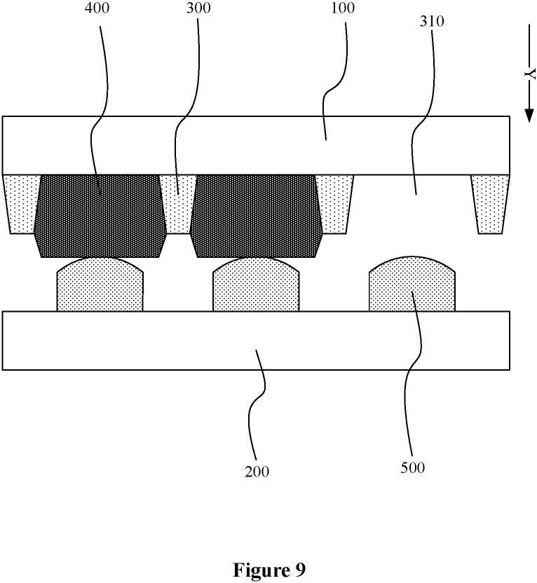

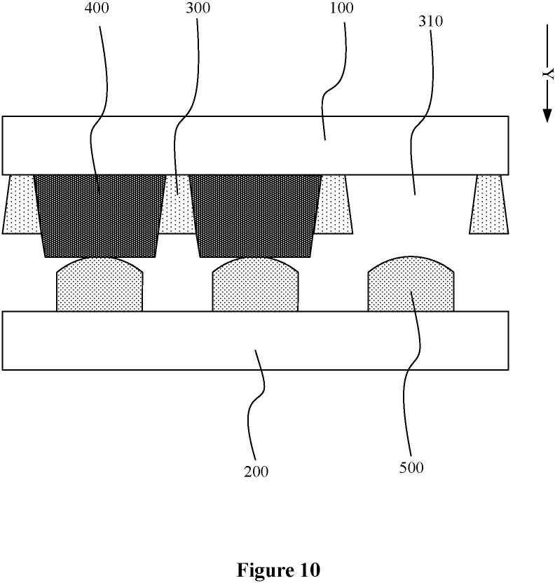

FIG. 10 is a schematic structural diagram of a display panel according to yet another embodiment of the present disclosure. A sectional area of the opening 310 on a surface parallel to the second substrate 200 is gradually decreased in the direction from the first substrate 100 to the second substrate 200. That is, in the direction Y from the first substrate 100 to the second substrate 200, the section of a portion of the metal bank 300 between two adjacent openings (that is, a transection in the direction of AA' shown in FIG. 1) is in an inverted trapezoid shape. That is, a surface area of the metal bank 300 at a side where the first substrate 100 is located is smaller than a surface area at a side where the metal bank 300 faces the second substrate 200. The metal bank 300 with inverted-trapezoid sections can function better in locking the reflected light, and to further improve the light emitting efficiency, to improve the display effect of the display panel.

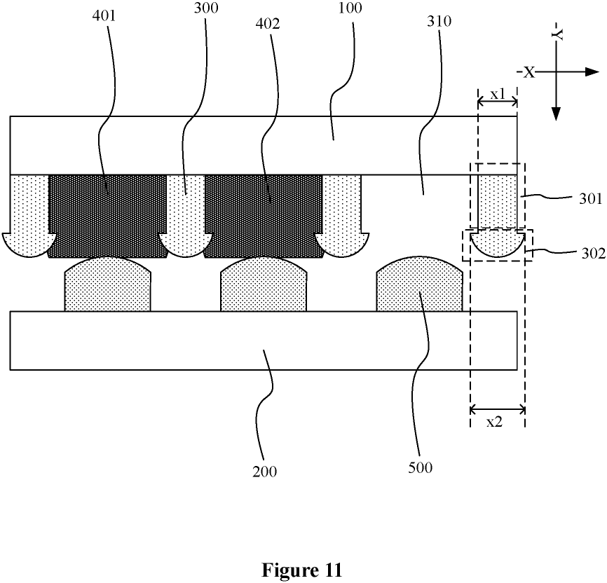

FIG. 11 is a schematic structural diagram of a display panel according to yet another embodiment of the present disclosure. Two adjacent light conversion layers are a first light conversion layer 401 and a second light conversion layer 402. In a direction X parallel to the direction from the light conversion layer 401 to the second light conversion layer 402, in a section along a direction Y parallel to the direction from the first substrate 100 to the second substrate 200: a portion of the metal bank 300 between two adjacent openings is in T shape. The metal bank 300 with T-shaped sections can also function better in locking the reflected light, and to further improve the light emitting efficiency, to improve the display effect of the display panel.

Referring to FIG. 11, in the direction from the first substrate 100 to the second substrate 200, the metal bank 300 includes a first part 301 and a second part 302. The first part 301 is located at a side close to the first substrate 100. A joint between the first part 301 and the second part 302 is a step shape. At the joint between the first part 301 and the second part 302, a width of the second part 302 x1 is greater than a width x2 of the first portion 301. In an embodiment, the T-shaped section of the metal bank 300 according to the present disclosure may be in a shape of mushroom or umbrella. That is, the second part 302 may be in a shape of a mushroom head or an umbrella cover. A width of the section of the second part 302 is gradually decreased in the direction from the first substrate 100 to the second substrate 200. The shape of the metal bank is not limited in the present disclosure.

FIG. 12 is a schematic structural diagram of a display panel according to yet another embodiment of the present disclosure. The metal bank 300 includes a first bank surface 330 facing away from the first substrate 100. The light conversion layer 400 includes a first light conversion surface 430 facing away from the first substrate 100. In the direction Y from the first substrate 100 to the second substrate 200, a distance d1 between the first bank surface 330 and a surface of the first substrate 100 is smaller than a distance d2 between the first light conversion surface 430 and the same surface of the first substrate 100. That is, in the direction Y from the first substrate 100 to the second substrate 200, a thickness of the metal bank 300 is smaller than a thickness of the light conversion layer 400, and not only the supporting capacity of the light emitting element 500 and the light conversion layer 400 which are in contact is improved, but also the conversion efficiency of the light conversion layer 400 is improved, to improve the display effect of the display panel.

In an embodiment of the present disclosure, in the direction Y from the first substrate 100 to the second substrate 200: the thickness of the metal bank 300 is greater than 1 µm; and the thickness of the light conversion layer 400 ranges from 2 µm to 6 µm. The thickness of the metal bank and the thickness of the light conversion layer are not limited in the present disclosure.

In an embodiment of the present disclosure, the light conversion layer 400 is a quantum dot light conversion layer. The term “quantum dot” indicates material with particles having three-dimensional size of nanometer order. Quantum dots with different sizes have different fluorescence effect and can excite the light field of different colors. The quantum dot light conversion layer according to an embodiment of the present disclosure is formed by adding quantum dot material to the conventional film layer, and the quantum dot light conversion layer may by excited to generate light with corresponding color. FIG. 13 is a schematic structural diagram of a display panel according to yet another embodiment of the present disclosure. The light conversion layer 400 includes a first light conversion surface 430 facing away from the first substrate 100. The first light conversion surface 430 is a convex surface or a concave surface, and the light emitting effect of the light conversion layer 400 can be improved.

It can be understood that, in the embodiments according to the present disclosure, the bank 300 is made of metal and the thickness of the metal bank 300 is smaller than the thickness of the light conversion layer 400, thus material spillage during the preparation of the light conversion layer 400 can be improved, and the bank made of metal facilitates the formation of the light conversion layer 400 according to the embodiment of the present disclosure, which is benefit to the utilization of light. In addition, the surface of the light conversion layer 400 facing the second substrate 200 according to the present disclosure is a convex surface or a concave surface facing the second substrate 200, which can improve the light emitting effect of the light conversion layer 400. Further, according to the embodiment of the present disclosure, the surface of the light conversion layer 400 facing the second substrate 200 is in contact with the surface of the light emitting element 500 facing the first substrate 100, which can improve the supporting between the first substrate 100 and the second substrate 200. In addition, according to the present disclosure, the surface of the light emitting element 500 facing the first substrate 100 may be a convex surface facing the first substrate 100, which can not only improve the light emitting effect of the light emitting element 500, but also improve the supporting performance between the light emitting element 500 and the light conversion layer 400. Further, according to the embodiment of the present disclosure, the section of a portion of the metal bank 300 between two adjacent openings may be in a T shape (such as mushroom shape or umbrella shape, etc.), which can function better in locking the light reflected by the metal bank 300, and to further improve the light emitting efficiency, to improve the display effect of the display panel.

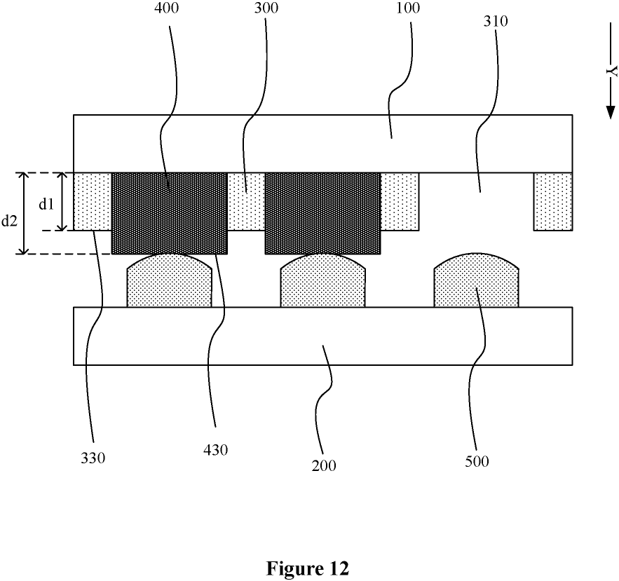

FIG. 14 is a schematic structural diagram of a display panel according to yet another embodiment of the present disclosure. The display panel further includes a color resistance layer 600 located between the light conversion layer 400 and the first substrate 100. A color of light allowed to be transmitted through the color resistance layer 600 is the same as a color of light converted by the light conversion layer 400. Light emitted by the light emitting element 500 is converted into a light with the predetermined color by the light conversion layer 400, and then the light passing through the light conversion layer 400 is filtered by the color resistance layer 600, and the purity of the light with the predetermined color is improved, to improve the display effect of the display panel. For example, in a case that the light conversion layer includes a green light conversion layer, the corresponding color resistance layer serves as a green light color resistance layer. The green light conversion layer converts the light emitted by the light emitting element into green light, and then the green color resistance layer filters the green light emitted from the green light conversion layer, and the purity of the green light emitted from the green color resistance layer is improved. In a case that the light conversion layer includes a red light conversion layer, the corresponding color resist layer serves as a red light color resistance layer. The red light conversion layer converts the light emitted by the light emitting element into red light, and then the red light color resistance layer filters the red light emitted from the red light conversion layer, and the purity of the red light emitted from the red light color resistance layer is improved, to improve the display effect of the display panel.

As shown in FIG. 14, in the direction Y from the first substrate 100 to the second substrate 200, there is no overlapping between the metal bank 300 and the color resistance layer 600 according to the embodiment of the present disclosure. That is, the color resistance layer 600 is located within the opening 310. In one embodiment, FIG. 15 is a schematic structural diagram of a display panel according to yet another embodiment of the present disclosure. In the direction Y from the first substrate 100 to the second substrate 200, the metal bank 300 overlaps with at least one of the adjacent color resistance layers 600. In a case that the metal bank 300 overlaps with two color resistance layers 600 among the adjacent color resistance layers 600, the adjacent color resistance layers 600 have the same thickness in the direction Y (that is, the surfaces of the adjacent color resistance layers 600 facing away from the first substrate 100 are flushed with each other), to avoid influence on the precision of preparing the metal bank 300 resulted from the unevenness of the different color resistance layers 600.

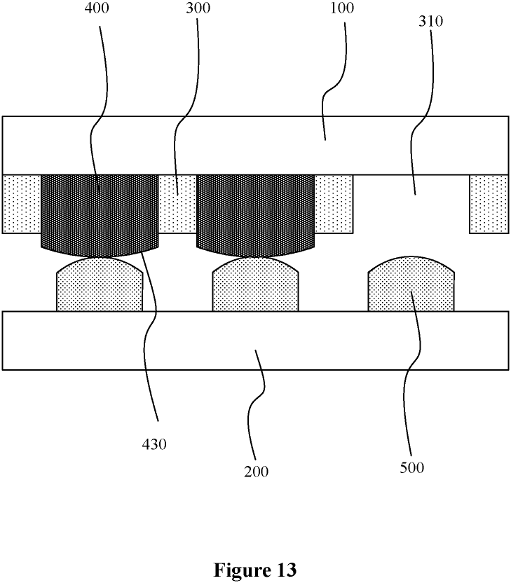

FIG. 16 is a schematic structural diagram of a display panel according to yet another embodiment of the present disclosure. The display panel further includes a bank seed layer 700 located between the metal bank 300 and the first substrate 100. A side of the bank seed layer 700 facing away from the first substrate 100 is in contact with the metal bank 300. The bank seed layer 700 may provide a position reference for the preparation of the metal bank 300, which can not only improve the quality of the metal bank 300, but also prevent the misalignment of the metal bank 300 and the color resistance layer 600 during the preparation process. The material of the bank seed layer 700 may be the same as the material of the metal bank 300 according to the embodiment of the present disclosure, which is not limited in the present disclosure.

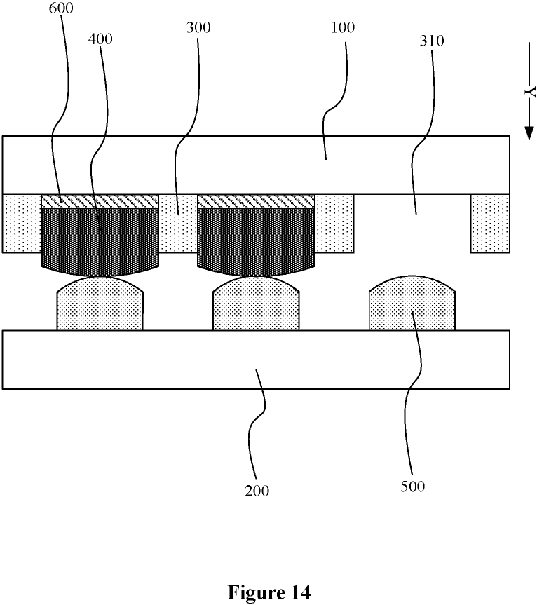

FIG. 17 is a schematic structural diagram of a display panel according to yet another embodiment of the present disclosure. The display panel further includes a black matrix layer 800 located between the metal bank 300 and the first substrate 100. The light blocking function of the black matrix layer 800 may avoid light leakage in the display panel and avoid color mixing between adjacent light conversion layers. It should be noted that, in a case that the display panel includes a black matrix layer, a color resistance layer and a bank seed layer, the black matrix layer is prepared at first, then the color resistance layer is prepared at the hollow of the black matrix layer, and finally the bank seed layer is prepared. That is, the bank seed layer is located between the black matrix layer and the metal bank.

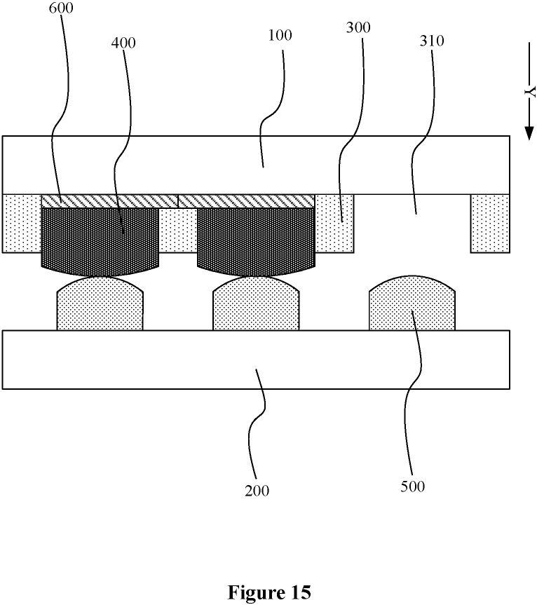

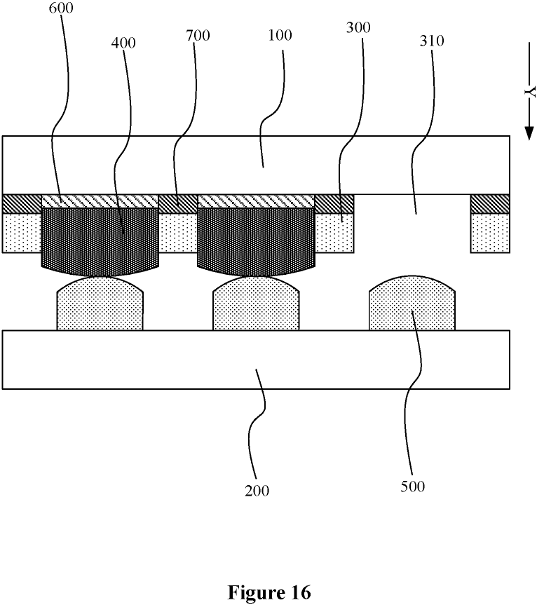

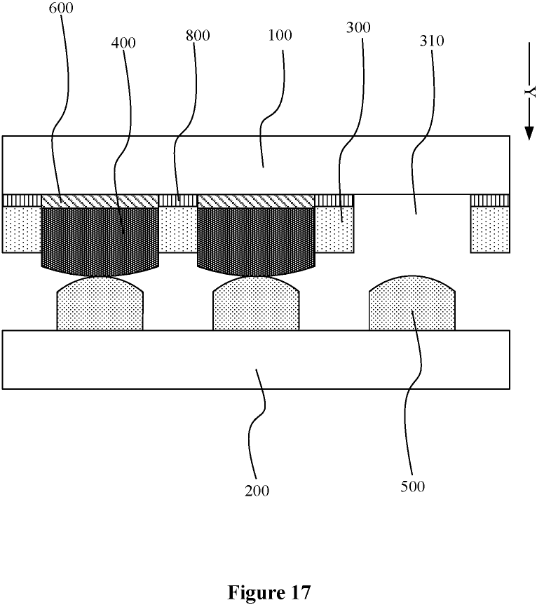

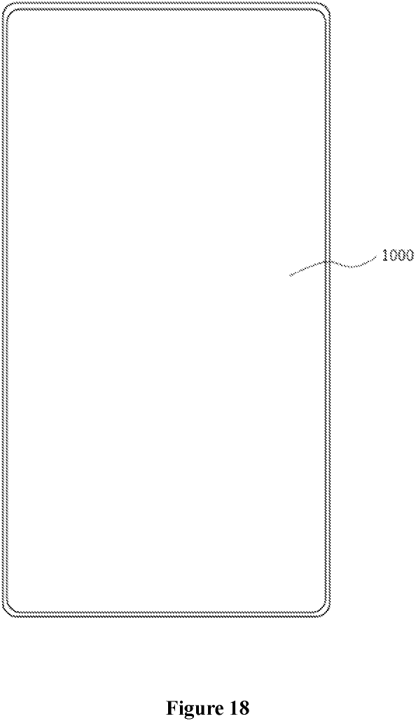

In addition, a display device is provided according to an embodiment of the present disclosure. The display device includes the display panel according to any one of the above embodiments. FIG. 18 is a schematic structural diagram of a display device according to an embodiment of the present disclosure. According to an embodiment of the present disclosure, the display device 1000 may be a mobile terminal device.

In other embodiments, the display device according to the present disclosure may be an electronic display device such as a computer and a wearable display device, which is not limited in the present disclosure.

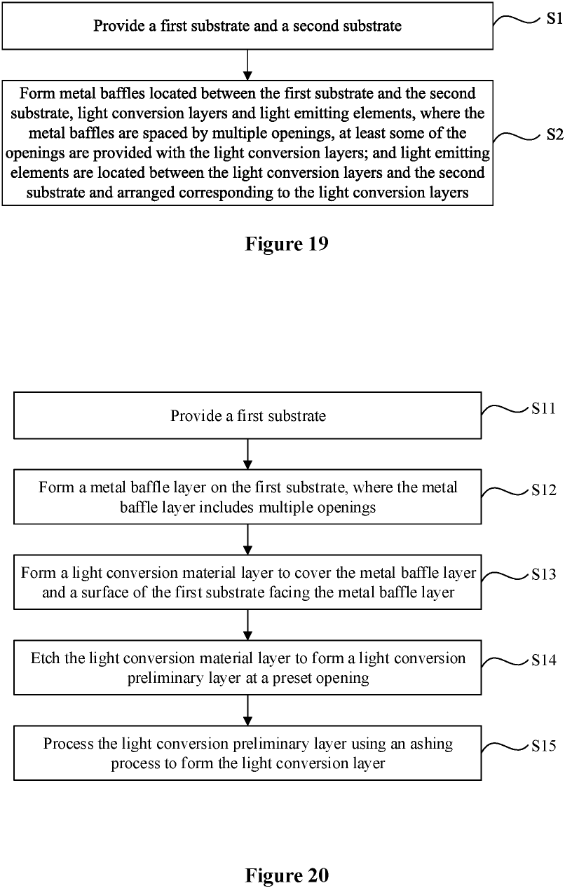

In addition, a method for manufacturing the display panel according to any one of the above embodiments is provided according to an embodiment of the present disclosure. FIG. 19 is a flowchart of a method for manufacturing a display panel according to an embodiment of the present disclosure. The method for manufacturing a display panel includes the following steps.

In S1, a first substrate and a second substrate are provided.

In S2, a metal bank located between the first substrate and the second substrate, light conversion layers and light emitting elements are formed. The metal bank includes multiple openings. At least some of the openings are provided with the light conversion layers. The light emitting elements are located between the light conversion layers and the second substrate, where the light conversion layers are arranged corresponding to at least some of the light emitting elements.

The manufacturing method according to the embodiment of the present disclosure is described in more details below with reference to the accompanying drawings. FIG. 20 is a flowchart of a method for preparing a light conversion layer according to an embodiment of the present disclosure. The method for preparing a light conversion layer includes the following steps.

In S11, a first substrate is provided.

In S12, a metal bank is formed on the first substrate, where the metal bank includes multiple openings.

In S13, a light conversion material layer is formed to cover the metal bank and a surface of the first substrate facing the metal bank.

In S14, the light conversion material layer is etched to form a light conversion preliminary layer at a preset opening.

In S15, the light conversion preliminary layer is processed using an ashing process to form the light conversion layer.

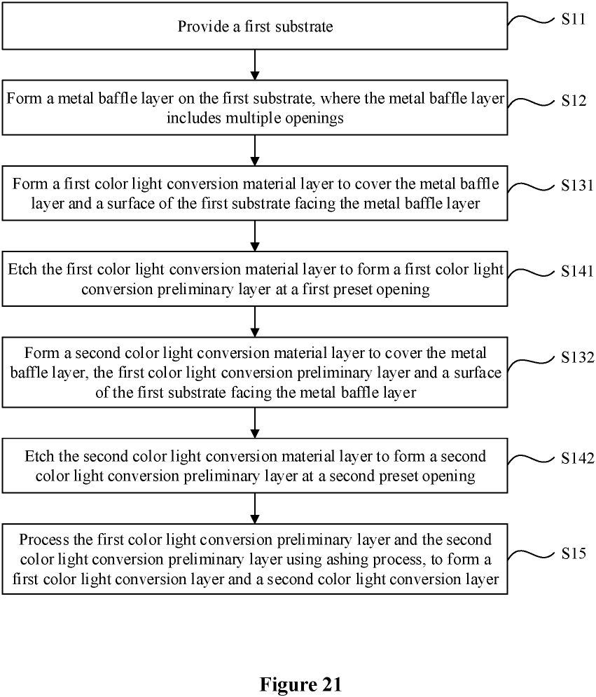

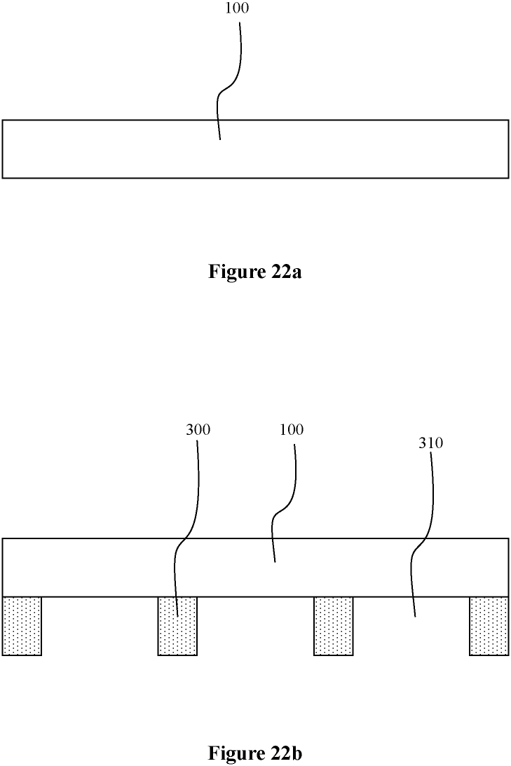

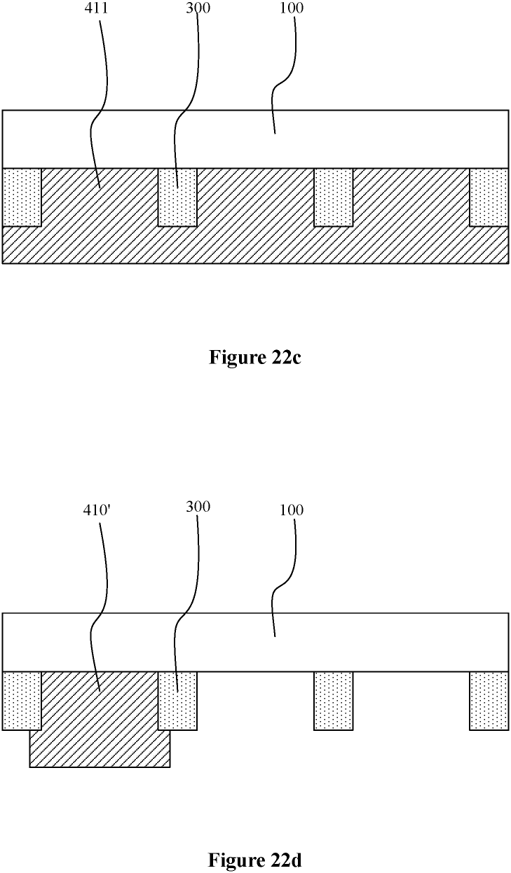

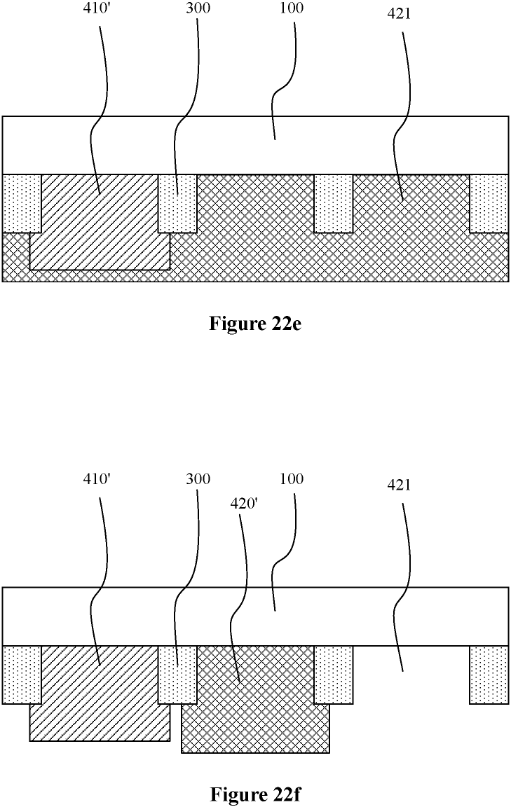

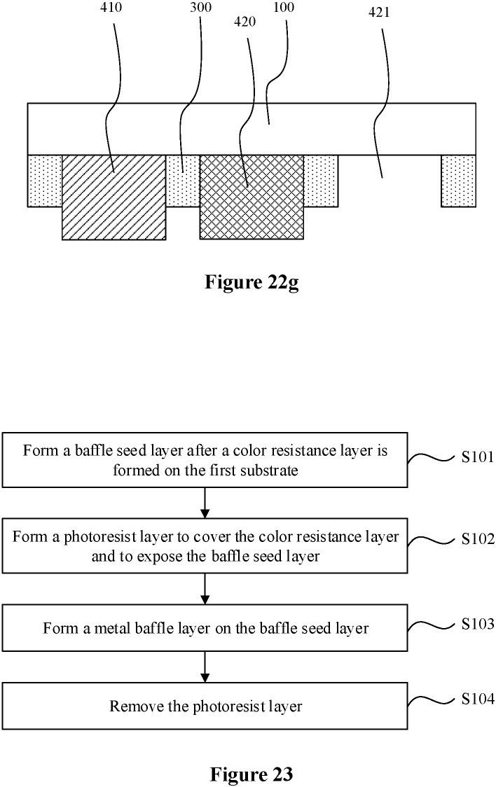

In an embodiment of the present disclosure, the light conversion layers according to the present disclosure may include light conversion layers for different colors, which may be prepared by different preparation processes. In one embodiment, referring to FIG. 21 to FIG. 22g, FIG. 21 is a flowchart of a method for preparing a light conversion layer according to another embodiment of the present disclosure, and FIG. 22a to FIG. 22g are schematic diagrams illustrating structures corresponding to the steps in FIG. 21. The light conversion layers include a first color light conversion layer 410 and a second color light conversion layer 420. The method for preparing the light conversion layer includes the following steps.

In S11, a first substrate is provided.

In S12, a metal bank is formed on the first substrate, where the metal bank includes multiple openings.

In S131, a first color light conversion material layer is formed to cover the metal bank and a surface of the first substrate facing the metal bank.

In S141, the first color light conversion material layer is etched to form a first color light conversion preliminary layer at a first preset opening.

In S132, a second color light conversion material layer is formed to cover the metal bank, the first color light conversion preliminary layer and a surface of the first substrate facing the metal bank.

In S142, the second color light conversion material layer is etched to form a second color light conversion preliminary layer at a second preset opening.

In S15, the first color light conversion preliminary layer and the second color light conversion preliminary layer are processed using an ashing process, to form a first color light conversion layer and a second color light conversion layer.

As shown in FIG. 22a, corresponding to step S11, a first substrate 100 is provided.

As shown in FIG. 22b, corresponding to step S12, a metal bank 300 is formed on the first substrate 100, where the metal bank includes multiple openings 310, and the metal bank 300 is formed as a grid.

In an embodiment of the present disclosure, the metal bank 300 according to the present disclosure may be formed by electroplating.

As shown in FIG. 22c, corresponding to step S131, a first color light conversion material layer 411 is formed to cover the metal bank 300 and a surface of the first substrate 100 facing the metal bank 300.

As shown in FIG. 22d, corresponding to step S141, the first color light conversion material layer 411 is etched to form a first color light conversion preliminary layer 410' at a first preset opening 310.

As shown in FIG. 22e, corresponding to step S132, a second color light conversion material layer 421 is formed to cover the metal bank 300, the first color light conversion preliminary layer 410' and a surface of the first substrate 100 facing the metal bank 300.

As shown in FIG. 22f, corresponding to step S142, the second color light conversion material layer 421 is etched to form a second color light conversion preliminary layer 420' at a second preset opening 310.

As shown in FIG. 22g, corresponding to step S15, the first color light conversion preliminary layer and the second color light conversion preliminary layer are processed using an ashing process, to form a first color light conversion layer 410 and a second color light conversion layer 420.

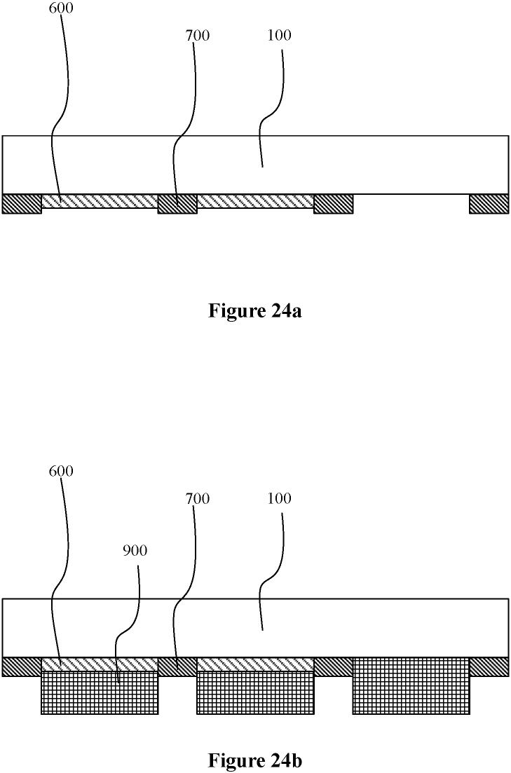

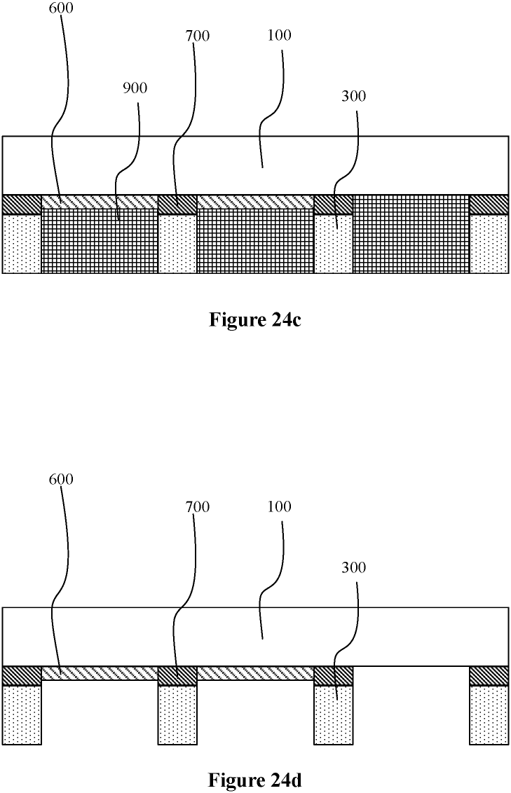

Further, the display panel according to the embodiment of the present disclosure may further include a color resistance layer and a bank seed layer. When preparing the light conversion layer, the color resistance layer may be prepared at first, and then the bank seed layer may be prepared. FIG. 23 is a flowchart of a method for preparing a metal bank according to an embodiment of the present disclosure, and FIG. 24a to FIG. 24d are schematic diagrams illustrating structures corresponding to the steps in FIG. 23. The display panel further includes a color resistance layer located between the light conversion layer and the first substrate, and the display panel further includes a bank seed layer located between the metal bank and the first substrate. Before forming the metal bank, the method further includes the following steps.

In S101, a bank seed layer is formed after a color resistance layer is formed on the first substrate.

In S102, a photoresist layer is formed to cover the color resistance layer while expose the bank seed layer.

In S103, a metal bank is formed on the bank seed layer.

In S104, the photoresist layer is removed.

As shown in FIG. 24a, corresponding to step S101, a bank seed layer 700 is formed after a color resistance layer 600 is formed on the first substrate 100.

As shown in FIG. 24b, corresponding to step S102, a photoresist layer 900 is formed to cover the color resistance layer 600 and expose the bank seed layer 700.

As shown in FIG. 24c, corresponding to step S103, a metal bank 300 is formed on the bank seed layer 700. The metal bank 300 may be formed by electroplating.

As shown in FIG. 24d corresponding to step S104, the photoresist layer 900 is removed, to form the metal bank 300.

A display panel and a method for manufacturing the display panel, and a display device are provided according to embodiments of the present disclosure. The display panel includes: a first substrate and a second substrate which are arranged opposite to each other; a metal bank located between the first substrate and the second substrate, where the metal bank includes multiple openings, and at least some of the openings are each provided with a light conversion layer; and light emitting elements located between the light conversion layers and the second substrate, where the light conversion layers are arranged corresponding to at least some of the light emitting elements. It can be seen that, when the light conversion layer converts the light emitted from the light emitting element into the light with the corresponding color, the light from the adjacent openings is blocked by the metal bank, and to avoid the occurrence of light mixing in adjacent openings, to improve the display effect of the display device.

What is claimed is:

1. A display panel, comprising:
a first substrate and a second substrate which are arranged opposite to each other;
a metal bank located between the first substrate and the second substrate, wherein the metal bank comprises a plurality of openings, and at least some of the openings are each provided with a light conversion layer; and
light emitting elements, which are located between the light conversion layers and the second substrate, wherein the light conversion layers are arranged corresponding to at least some of the light emitting elements.

2. The display panel according to claim 1, wherein a side wall of the metal bank at the openings is a reflecting surface.

3. The display panel according to claim 1, wherein a surface of the metal bank facing away from the first substrate is a non-reflecting surface.

4. The display panel according to claim 3, wherein the surface of the metal bank facing away from the first substrate is an oxidized surface.

5. The display panel according to claim 1, wherein a side of one of the light emitting elements facing away from the second substrate is in contact with a side of the light conversion layer facing away from the first substrate.

6. The display panel according to claim 1, wherein the metal bank is electrically connected to a reference signal terminal.

7. The display panel according to claim 1, wherein a material of the metal bank comprises at least one of Ni and Al.

8. The display panel according to claim 1, wherein a sectional area of one opening on a surface parallel to the second substrate is gradually increased, decreased or remains the same in a direction from the first substrate to the second substrate.

9. The display panel according to claim 1, wherein two adjacent light conversion layers are a first light conversion layer and a second light conversion layer, in a direction parallel to a direction from the first light conversion layer to the second light conversion layer and in a section parallel to a direction from the first substrate to the second substrate:
a portion of the metal bank between two adjacent openings is in a T shape.

10. The display panel according to claim 9, wherein in the direction from the first substrate to the second substrate, the metal bank comprises a first part and a second part, wherein the first part is located at a side close to the first substrate;
a joint between the first part and the second part is in a step shape; and at the joint between the first part and the second part, a width of the second part is greater than a width of the first part.

11. The display panel according to claim 1, wherein the metal bank comprises a first bank surface facing away from the first substrate, and the light conversion layer comprises a first light conversion surface facing away from the first substrate;
in the direction from the first substrate to the second substrate, a distance between the first bank surface and a surface of the first substrate is smaller than that between the first light conversion surface and the same surface of the first substrate.

12. The display panel according to claim 1, wherein in the direction from the first substrate to the second substrate:
a thickness of the metal bank is greater than 1 µm; and
a thickness of the light conversion layer is 2 µm to 6 µm.

13. The display panel of claim 1, wherein the light conversion layer is a quantum dot light conversion layer.

14. The display panel according to claim 1, wherein the light conversion layer comprises a first light conversion surface facing away from the first substrate, the first light conversion surface is a convex surface or a concave surface.

15. The display panel according to claim 1, wherein the display panel further comprises a color resistance layer located between the light conversion layer and the first substrate, and a color of light allowed to be transmitted through the color resistance layer is the same as a color of light converted by the light conversion layer.

16. The display panel according to claim 15, wherein the display panel further comprises a bank seed layer located between the metal bank and the first substrate, a side of the bank seed layer facing away from the first substrate is in contact with the metal bank.

17. The display panel of claim 15, wherein the display panel further comprises a black matrix layer located between the metal bank and the first substrate.

18. A display device, comprising a display panel, wherein the display panel comprises:
a first substrate and a second substrate which are arranged opposite to each other;
a metal bank located between the first substrate and the second substrate, wherein the metal bank comprises a plurality of openings, and at least some of the openings are each provided with a light conversion layer;
light emitting elements, which are located between the light conversion layers and the second substrate, wherein the light conversion layers are arranged corresponding to at least some of the light emitting elements.

19. A method for manufacturing a display panel, comprising:
providing a first substrate and a second substrate;
forming a metal bank located between the first substrate and the second substrate, light conversion layers and light emitting elements, wherein the metal bank comprises a plurality of openings, at least some of the openings are provided with the light conversion layers; and the light emitting elements are located between the light conversion layers and the second substrate, wherein the light conversion layers are arranged corresponding to at least some of the light emitting elements.

20. The method according to claim 19, wherein forming the light conversion layers comprises:
providing the first substrate;
forming the metal bank on the first substrate, wherein the metal bank comprises the plurality of openings;
forming a light conversion material layer to cover the metal bank and a surface of the first substrate facing the metal bank;
etching the light conversion material layer to form a light conversion preliminary layer at a preset opening;
processing the light conversion preliminary layer using an ashing process to form the light conversion layer.

21. The method according to claim 19, wherein the light conversion layers comprise a first color light conversion layer and a second color light conversion layer, wherein forming the light conversion layers comprises:
providing the first substrate;
forming the metal bank on the first substrate, wherein the metal bank comprises the plurality of openings;
forming a first color light conversion material layer to cover the metal bank and a surface of the first substrate facing the metal bank;
etching the first color light conversion material layer to form a first color light conversion preliminary layer at a first preset opening;
forming a second color light conversion material layer to cover the metal bank, the first color light conversion preliminary layer and a surface of the first substrate facing the metal bank;
etching the second color light conversion material layer to form a second color light conversion preliminary layer at a second preset opening;
processing the first color light conversion preliminary layer and the second color light conversion preliminary layer using an ashing process to form the first color light conversion layer and the second color light conversion layer.

22. The method according to claim 20, wherein the display panel further comprises a color resistance layer located between the light conversion layers and the first substrate, and the display panel further comprises a bank seed layer located between the metal bank and the first substrate, and before forming the metal bank, the method further comprises:
forming a bank seed layer after a color resistance layer on the first substrate is formed;
forming a photoresist layer to cover the color resistance layer and to expose the bank seed layer;
forming the metal bank on the bank seed layer; and
removing the photoresist layer.
